(19) United States
(12) Patent Application Publication
(10) Pub. No.: US 2011/0272020 A1
(43) Pub. Date: Nov. 10, 2011

(54) SOLAR CELL AND METHOD FOR PRODUCING A SOLAR CELL FROM A SILICON SUBSTRATE

(75) Inventors: Daniel Biro, Freiburg (DE); Oliver Schultz-Wittmann, Sunnyvale, CA (US); Anke Lemke, Berlin (DE); Jochen Rentsch, Freiburg (DE); Florian Clement, Freiburg (DE); Marc Hofmann, Gottenheim (DE); Andreas Wolf, Freiburg (DE); Luca Gautero, Imperia (IT); Sebastian Mack, Freiburg (DE); Ralf Preu, Freiburg (DE)

(73) Assignee: FRAUNHOFER-GESELLSCHAFT ZUR FORDERUNG DER ANGEWANDTEN FORSCHUNG E.V.

(21) Appl. No.: 13/144,531

(22) PCT Filed: Dec. 3, 2009
(86) PCT No.: PCT/EP09/08605

§ 371 Date: Jul. 14, 2011

(30) Foreign Application Priority Data
Jan. 14, 2009 (DE) 10 2009 005 168.6

(51) Int. Cl. H01L 31/0232; H01L 31/18

(52) U.S. Cl. 136/256; 438/72; 257/E31.001

(57) ABSTRACT

A method for producing a solar cell from a silicon wafer, including the following process steps: A) texturizing one side of the silicon substrate (1) for improving the absorption or removing saw damage on one side of the silicon substrate (1); B) generating an emitter area (2) on one side of the silicon substrate (1) by diffusing in a doping material for forming a pn transition; C) removing a glass layer which comprises the doping material; D) applying a masking layer (3) which is a dielectric layer; E) removing one part of the material of the silicon substrate (1); F) applying metal structures (5, 6) for electrically contacting the solar cell. It is significant that thermal oxidation is performed between the process steps E and F for forming an oxide layer (4) and that the masking layer (3) and the oxide layer (4) remain on the silicon substrate (1) in the subsequent process steps.

### BACKGROUND

The invention relates to a method for producing a solar cell with a front side and a back side from a silicon substrate, as well as to a solar cell produced according to this method.

For producing solar cells from a silicon substrate, a plurality of methods are known. Typically, such methods comprise, beginning with a homogeneous n-doped or p-doped silicon wafer, the following processing steps: generation of a texture for improving the optical properties on the front side of the silicon substrate, execution of a diffusion process on the front side for generating an emitter and for the formation of a pn junction, removal of a silicate glass forming during the preceding diffusion, deposition of an anti-reflex layer for further improvement of the optical properties on the front side of the silicon substrate, and finally deposition of metallization structures on the front side and back side of the solar cell for electrical contacting of the emitter via the front-side metallization and of the rest of the substrate (the base) via the back-side metallization.

For industrial solar cells produced with such methods, typically the entire back side is covered over the whole surface area with an aluminum silicon mixture. This has the disadvantage that the efficiency of the solar cell is reduced due to the low passivation effect, i.e., a high recombination rate and thus a loss of charge-carrier pairs for the electrical energy production. Furthermore, the back side of such a solar cell has a low optical reflection effect, so that electromagnetic radiation incident into the solar cell via the front side is partially absorbed on the back side and thus not available for further generation of charge-carrier pairs. This causes a further reduction of the efficiency of the solar cell.

Indeed, processing sequences are known that partially eliminate the previously mentioned disadvantages, but these processing sequences represent a large modification of the known processing sequence, so that these can only be integrated into already existing industrial manufacturing processes with great effort and result in a considerable increase in the production costs.

In order to achieve better passivation of the back side of the solar cell, it is known to perform, after diffusion of the emitter on the deposition of an anti-reflection layer constructed as a silicon-nitride layer on the front side of the silicon substrate, a material removal on the back side of the solar cell, in order to remove an emitter possibly diffused onto the back side and then to deposit a layer structure for passivation on the back side by PECVD (Plasma Enhanced Chemical Vapor Deposition). The layer structure consists of a first layer of SiOxNY:H and a layer of SiNX:H. Such a process is described in Industrial Type Cz Silicon Solar Cells With Screen-Printed Fine Line Front Contacts And Passivated Rear Contacted By Laser Firing, Marc Hofmann et al., 23rd European Photovoltaic Solar Energy Conference and Exhibition, Sep. 1-5, 2008, Valencia, Spain.

### SUMMARY

Starting from here, the present invention is based on the objective of providing an alternative processing sequence that leads to improved passivation in comparison with previously known methods, especially of the back side of the solar cell and/or makes possible a good passivation effect with simpler and more economical processing steps. Furthermore, with the present invention, a method is provided that, on one hand, increases the efficiency of the solar cell produced by means of this method and, on the other hand, allows an integration of the new method easily into known manufacturing processes.

This objective is achieved by a method and by a solar cell according to the invention. Advantageous constructions of the method according to the invention and the solar cell are described below.

The method according to the invention for producing a solar cell with a front side and a back side from a silicon substrate, in particular, a silicon wafer, comprises the following processing steps:

In a processing step A, a texture is generated on at least one side of the silicon substrate for improving the absorption when electromagnetic radiation is incident on the solar cell and/or removal of the cutting damage is carried out on at least one side of the silicon substrate. “Cutting damage” designates those impurities and unevenness or defects in the crystal structure at the surfaces of the silicon substrate that are created in the production of the silicon substrate by cutting. Advantageously, a texture is realized on the monocrystalline silicon by etching the solar cell in a KOH or a NaOH solution in which isopropyl alcohol or other organic components are contained.

For polycrystalline silicon, etching is advantageously carried out in a mixture from HNO3 and HF. Other methods also lie in the scope of the invention in which a texture is realized by other wet-chemical methods and/or masking processes (e.g., photolithography steps) or is carried out by means of plasma or laser processes.

Advantageously, the method is carried out on an already homogeneously doped silicon substrate; alternatively a homogeneous doping of the silicon substrate as a preceding processing step also lies in the scope of the invention.

In a step B, an emitter region is generated at least on sub-regions of at least one side of the silicon substrate through the diffusion of at least one dopant. The dopant is here selected such that a doping of the opposite type in comparison to the homogeneous doping of the silicon substrate is carried out. Typically, the method is applied to homogeneous, p-doped silicon substrates, so that an n-doped emitter is generated accordingly in the processing step B. Likewise, however, an inversion lies within the scope of the invention, i.e., the use of a homogeneously n-doped silicon substrate and accordingly the production of a p-doped emitter region in processing step B due to the opposite-type dopants forms a pn junction between the generated emitter region and the adjacent, homogeneously doped region of the silicon substrate (the base).

In connection with the generation of the emitter region in processing step B, residue is produced on the surfaces of the silicon substrate in the form of a glass layer containing the dopant. If, for example, the emitter region is generated by means of the diffusion of the dopant boron, then a borosilicate glass is formed on the surfaces.

Therefore, in a processing step C, the removal of a glass layer is carried out on at least one side of the silicon substrate, wherein the glass layer contains the dopant. Advantageously, the removal is carried out on the front side and back side of the silicon substrate. The glass layer could be produced, for example, during the diffusion of a dopant from the gas phase or at first a glass layer containing the dopant could be deposited in step B, for the diffusion of the dopant.

In a processing step D, a masking layer is deposited at least on at least one sub-region of at least one side of the silicon substrate, wherein the masking layer is a dielectric layer.

Then, in a processing step E, at least one part of the material of the silicon substrate is removed on at least one side of the silicon substrate and/or at least one side of the surface is conditioned. Conditioning is a surface treatment that has the effect that, in a subsequent passivation step, a better electrical passivation of the conditioned surface is achieved. Advantageously, the conditioning comprises a slight material removal. Advantageously, in this material removal, the emitter on the surface regions of the silicon substrate is removed at which no emitter is desired, for example, on the back side of the silicon substrate for the production of a standard solar cell structure. It likewise lies in the scope of the invention that additionally after removal of the emitter or alternatively only surface conditioning is carried out at least of sub-regions of the surface of the silicon substrate.

In a processing step F, metallization structures are deposited on the front side and/or back side of the silicon substrate for the electrical contacting of the solar cell, in particular, for the electrical contacting of the homogeneously doped region of the silicon substrate on one side and of the emitter region on the other side.

It is essential now that, between the processing steps E and F, in a processing step E2, a thermal oxidation is carried out for the formation of a thermal oxide layer in a sub-region of the front side and/or back side of the silicon substrate that is not covered by the masking layer deposited in step D. Thus, in the method according to the invention, an at least partial covering of at least one side of the silicon substrate is carried out with the oxide layer formed by means of thermal oxidation. It is essential furthermore that both the masking layer and also the oxide layer are not removed again from the solar cell in the subsequent processing steps. In contrast to masking layers that are used, for example, in photolithographic processes merely for the formation of structure and then removed again, for the method according to the invention, both the masking layer and also the oxide layer remain essentially on the solar cell, i.e., in particular, a complete removal of the oxide layer or the masking layer is not carried out. The background for this is that the masking layer and the oxide layer are used for improving the surface passivation and/or the optical properties with respect to electromagnetic radiation incident into the solar cell. The thermal oxidation advantageously takes place in a tubular furnace or in a tunnel machine, advantageously in a processing atmosphere in which an oxygen source, for example, oxygen or ozone is contained in the form of O2 or O3. For accelerating the oxidation, water vapor is advantageously also contained in the processing atmosphere. Furthermore, advantageously DCE (dichloroethylene) is contained in the processing atmosphere for accelerating the oxidation. For further acceleration of the oxidation, this could also be carried out under increased pressure in the processing chamber.

The method according to the invention thus differs from previously known methods initially in that the two mentioned layers remain on the solar cell. Compared with the previously known methods mentioned above in which a layer structure is deposited on the back side of the solar cell by PECVD for improving the passivation effect, the method according to the invention differs especially in that, by means of thermal oxidation, a thermal oxide layer is deposited.

The designation “oxide layer” here designates a layer that is generated by means of thermal oxidation and is typically produced from the oxidation of the surface of the silicon substrate. Due to this, the oxide layer could contain silicon and could be constructed, for example, as SiO2 layer or in a different stoichiometric ratio than SiOx.

The use of an oxide layer has the advantage that, for simultaneously very good passivation of the surface, a low density of charges fixed in the passivation layer is achieved. In particular, in the use of a p-type substrate, the formation of high densities of positive charges in the passivating layers can lead to the result that negative charges build up as a mirror charge at the boundary surface to this layer within the silicon. It is known that these mirror charges can form an inversion layer and can lead to current loss of the solar cell via a short circuit with the back side contacts.

In particular, the use of an oxide layer generated by means of thermal oxidation has the advantage that such oxide layers have a boundary surface that can be passivated well relative to the surface of the silicon substrate, because, due to the oxidation, the oxide layer “grows” slightly into the substrate surface and therefore has a more suitable surface compared with oxide layers deposited by other methods.

The previously mentioned methods used the starting point that the deposition of an oxide layer through thermal oxidation has several disadvantages:

First, an oxide layer is suitable as an anti-reflection layer for a solar cell only conditionally, as long as encapsulation of the solar cell in a module is desired. In this case, the index of refraction of an oxide layer produced by means of thermal oxidation is a disadvantage for the optical properties of the solar cell. In addition, in the previously mentioned method, it could not be prevented that, in the passivation of, for example, the back side of a solar cell by means of an oxide layer, an oxide layer forms on the front side of the solar cell that leads to the mentioned disadvantages with respect to the optical properties. In particular, the effect has proven disadvantageous that an oxide layer grows more quickly on textured surfaces like typically the front side of a solar cell in thermal oxidation than on a planar surface like typically the back side of the solar cell.

Another disadvantage is that the formation of an oxide layer by means of thermal oxidation on a surface on which an emitter region is formed leads to a partial consumption of the emitter region, so that the electrical properties of the solar cell are negatively affected.

Advantageously, the masking layer therefore has the property that it inhibits the formation of an oxide layer, especially for thermal oxidation on the masking layer. Studies of the applicant have shown that such an effect inhibiting the formation of an oxide layer consists especially in the formation of the masking layer as a silicon nitride layer or as a silicon carbide layer.

In this advantageous embodiment, it is thus possible, for the first time, to mask sub-regions of the surfaces of the silicon substrate by means of a masking layer and then to carry out a thermal oxidation that leads, due to the inhibiting effect of the masking layer with respect to the formation of an oxide layer, essentially to a formation of an oxide layer in the region not covered by the masking layer. Thus, in this way, the advantages of the passivating effect of an oxide layer can be used for a solar cell produced with the method according to the invention and simultaneously the previously mentioned disadvantages are avoided in the formation of a parasitic oxide layer, especially on a textured front side and/or on a surface on which an emitter is arranged. In particular, it is advantageous to form the masking layer on that side of the solar cell on which electromagnetic radiation is incident on the solar cell and to form the masking layer as an anti-reflection layer. Advantageously, here the masking layer is formed as a silicon nitride layer, because the use of a silicon nitride layer as an anti-reflection layer is typical and thus processing can revert to previously known processing sequences.

Here it is advantageous for the masking layer formed as an anti-reflection layer to optimize the anti-reflection effect after the completion of the processing of the solar cell, in particular, a thickness of the anti-reflection layer in a range between 50 nm to 150 nm, in particular, in a range from 60 nm to 100 nm, and advantageously in a range from 65 nm to 90 nm is advantageous.

The masking layer could be deposited in various ways, advantageously through PECVD, sputtering, or APCVD. The index of refraction of the masking layer advantageously equals ca. 2.1. However, indexes of refraction of 1.9-2.7, in particular, 2.0-2.3, could also be used meaningfully. In particular, it is advantageous if the index of refraction assumes different values within the layer.

In another advantageous embodiment of the method according to the invention, the masking layer is deposited in processing step D essentially only on a masking layer side that is the front side or the back side of the silicon substrate. This is desirable, for example, if, as described above, the masking layer is formed as an anti-reflection layer and is deposited, for example, on the front side of the silicon substrate.

Advantageously, the masking layer is formed such that it is removed not at all or only slightly through certain processes for material removal, in particular, through certain etching processes. In this advantageous embodiment of the method according to the invention, the masking layer is thus used not only for masking in the generation of the oxide layer in processing step E2, but also for masking in processing step E, such that, in processing step E at those regions of the surface of the silicon substrate that are covered by the masking layer, no or only little material is removed. Advantageously, the masking layer deposited in step D and the process of the material removal in step E are adjusted such that the material removal in step E does not remove or only slightly removes the masking layer.

If the masking layer is formed, for example, as a silicon nitride layer, then this layer is essentially resistant against etching by: concentrated alkali media such as KOH, NaOH, NH4OH, acid media such as concentrated HCl or HNO3 also at elevated temperatures, diluted HF and certain mixtures that contain hydrogen peroxide, such as HCl+H2O2, NH4OH+H2O2.

This resistance is sufficient for suitable layer selection, in order to remove silicon in regions in which silicon is not covered by the layer (in order to remove, for example, doped regions or otherwise disruptive regions), and/or in order to condition the uncovered regions, in order to allow, in subsequent steps (such as, for example, of a thermal oxidation), a very high-quality electrical passivation, while the mask protects the regions that should not be processed and is here attacked only insignificantly or also not in a disruptive way through selection of a suitable output thickness and can remain on the solar cell, in particular, as an anti-reflection layer.

Studies of the applicant have shown that also for one-side deposition of the masking layer, a masking layer is nevertheless often formed at least partially on the side of the silicon substrate opposite the masking layer side. Therefore, in one advantageous embodiment, in processing step E, on the side of the silicon substrate opposite the masking layer side, a one-side material removal is carried out for removing any sub-pieces of a masking layer undesirably deposited on the side opposite the masking layer side. Thus, in this advantageous embodiment, in step E, a one-side material removal is carried out exclusively and/or additionally, such that the masking layer is removed on this side.

If the masking layer is formed, for example, as a silicon nitride layer, then this layer could be etched, for example, with the following etchants, wherein silicon lying underneath could then also be removed (the resistance values are dependent on the density and composition of the layer and increase with increasing density): concentrated HF, concentrated mixtures from HF and water and HNO3, as well as hot and concentrated phosphoric acid. With such substances, the layer could be removed accordingly, at least in some regions.

Advantageously, this one-side material removal is carried out by means of rolling on an etchant, advantageously an acid substance, in particular, by means of rolling on a mixture made from at least HF and water or at least HNO3 and HF and water. The rolling is carried out advantageously in a tunnel machine. Alternatively, for example, a plasma etching process could also be applied (for example, by means of SF6 or NF3 or CF4 or F2 or by means of chlorine-containing plasmas). As excitation sources, different methods can be used: microwave, high-frequency, low-frequency, radiofrequency, DC, expanding thermal plasma excitations. These processes could also be used for pure conditioning without significant silicon removal (see below) when the processing settings are selected suitably.

In particular, it is advantageous that, in processing step E, initially the one-side material removal is carried out and then a surface conditioning of the silicon substrate is carried out, advantageously by an etching process by means of a KOH solution. It also lies in the scope of the invention to perform only a surface conditioning of the non-masked regions. For a material removal, typically a layer is removed with a thickness of at least 1 μm, for a pure surface conditioning, typically a removal of a layer with a thickness of less than 0.1 μm is carried out in many types of surface conditioning, also no material removal. The surface conditioning is carried out advantageously by an etching process, in particular, by means of an alkali solution, in particular, by means of a solution that contains KOH and/or NaOH and/or NH4OH.

Advantageously, the surface conditioning comprises additionally or alternatively the following steps:

Dipping in hydrofluoric acid (possibly diluted with water) or in a mixture made from ammonium hydroxide and hydrogen peroxide and water or in a mixture made from HCl and hydrogen peroxide and water or in a mixture made from H2SO4 and hydrogen peroxide and water. Furthermore, a cleaning by dipping in a mixture made from HNO3 and water could also be carried out, wherein these processing steps could also be combined. From the semiconductor processing technology, cleaning processes, such as RCA, SC1, SC2, Piranha, ozone-supported cleaning processes, Ohmi Clean, and IMEC Clean are know and can be used in connection with the present invention.

Especially advantageous are the constructions in which the temperatures of the mixtures are increased. Such cleaning methods and others that could be combined with that according to the invention are described, for example, in the Handbook of Silicon Wafer Cleaning Technology (Materials Science and Process Technology) Publisher: Elsevier; Edition: 2 (Dec. 1, 2007).

In the knowledge of the applicant, this substantiates that the previously described one-side material removal often leads to a surface character that cannot be easily passivated, so that a directly deposited oxide layer by means of thermal oxidation leads only to a lack of electrical passivation of this surface. Advantageously, therefore, after the material removal, initially a surface conditioning is carried out and then the thermal oxidation for deposition of the oxide layer is carried out.

Studies of the applicant have shown that the masking layer advantageously has a density between 2.3 g/cm3 to 3.6 g/cm3, in particular between 2.5 g/cm3 to 3.6 g/cm3, advantageously between 2.6 g/cm3 to 3.6 g/cm3, at most advantageously between 2.65 g/cm3 to 3.6 g/cm3. A masking layer with higher density has a greater resistance against subsequent processing steps, in particular, etching steps.

For the formation of a sufficient electrical passivation it is advantageous that, in processing step E2, the oxide layer is deposited with a thickness in the range between 4 nm and 200 nm, in particular, between 4 nm and 100 nm, advantageously between 4 nm and 30 nm, at most advantageously between 4 nm and 15 nm.

Studies of the applicant have further shown that an especially very high electrical passivation of a surface can be achieved in that, between the processing steps E2 and F, in a processing step E3, another layer is deposited on the oxide layer, so that a layer system exists. Advantageously, in processing step E3, a silicon nitride layer is deposited on the oxide layer, because this then leads to an especially good electrical passivation effect of the surface of the silicon substrate lying underneath. It also lies in the scope of the invention to deposit other layers and/or layer sequences on the oxide layer, for example, additional oxide layers, layers of the composition SiOXNY:H, SiNY:H, layers from amorphous silicon, silicon carbide, aluminum oxide, titanium dioxide, general metal oxides, metal nitrides, metal carbides, and mixed layers or multi-level layers.

For the formation of the masking layer as an anti-reflection layer, it is advantageous, in step F, to deposit a metallization structure on the anti-reflection layer and to cause a penetration of this metallization structure at least in some regions through the anti-reflection layer, so that the metallization structure is connected in an electrically conductive way to the silicon substrate lying below the anti-reflection layer or to the emitter region formed here. It also lies in the scope of the invention to structure the coatings before the metallization so that the metallization must not penetrate the layers, because the silicon is already accessible.

The method according to the invention is suitable for producing so-called standard solar cells, i.e., solar cells that have an emitter on the front side and a corresponding, typically comb-like metallization on the front side for the electrical contacting of the emitter and, on the back side, a metallization typically over the entire surface area for the contacting of the silicon substrate doped opposite the emitter.

Advantageously, the back side is not metallized homogeneously over the entire surface area, but instead has at least one, advantageously two metallized regions that can be soldered for connecting the solar cell to other solar cells for modular wiring, advantageously by means of solder contacts.

The method according to the invention is also suitable, however, for the formation of more complex structures of solar cells, for example, by the generation of only local contacts between the metallization of the back side. In particular, it is advantageous to provide the back side essentially over the entire surface area with at least the oxide layer deposited by means of thermal oxidation, to deposit on this layer a metal layer over the entire surface area and to generate locally a penetration of the metal layer through the oxide layer, for example, through local, thermal melting by means of a laser (so-called laser-fired contacts).

It also lies in the scope of the invention to generate other solar-cell structures by means of the method according to the invention. In particular, the method is to be used for producing so-called metallization wrapped through solar cells (MWT solar cells):

In one advantageous embodiment, before the processing step A, in a processing step A0, several recesses are formed in the silicon substrate that penetrate the silicon substrate essentially perpendicular to the front side.

The recesses are advantageously generated with an average diameter of 20 μm to 3 mm, in particular, 30 μm to 200 μm, advantageously 40 μm to 150 μm.

Advantageously, in processing step F, both on the front side and also on the back side of the silicon substrate, metallization structures are deposited and, in addition, a feed through of the metallization structures of the front side is carried out by means of metallization structures in the recesses on the back side of the silicon substrate.

The metallization structures on the back side are here formed such that back-side metallization structures and the metallization structures led through the recesses have no electrical contact. In this way, an MWT solar cell is generated that has the advantage that both the negative and also the positive pole of the electrical contacting can be contacted electrically by means of the back side of the solar cell.

It also lies in the scope of the invention to carry out the metallization through the recesses in a later processing step.

In the production of a MWT solar cell with the method according to the invention, a process D2 is advantageously inserted between the processing steps D and E in which a masking is carried out in some regions that prevents, in subsequent step E, the emitter from being removed if a corresponding etching method is applied in E. The masking is carried out especially in the recesses and in adjacent silicon regions. According to the configuration of process E, the masking that was deposited in D2 can be removed.

For the metallization of the solar cell, it can be achieved in that the emitter that can be contacted is also located in the holes and on the back side of the solar cell. In this way it is made possible to connect the metallization of the front side through the holes with a metallization of the back side, without a short circuiting of the regions separated by the pn junction taking place, because this metallization covers the emitter regions separated by the other metallization of the back side and thus has no electrical contact to the base.

With reference to the formation of the masking layer, the hydrogen content and/or the silicon content of the layer is advantageously selected such that the resistance of the layer is given (that is influenced by the hydrogen content, see, for example, in Dekkers et al., Solar Energy Materials and Solar Cells, 90 (2006) 3244-3250) for the subsequent processing steps.

In another advantageous embodiment of the method according to the invention for producing a MWT solar cell, between the processing steps E2 and F, an electrically insulating layer is deposited in the recesses. In this way it is prevented that, for feed through of the metallization, the metallization in the recesses penetrates through the recesses into the substrate and leads to recombination centers or to short circuiting. This layer could be, for example, the oxide layer and/or the masking layer or a coverage in some regions in the recesses could be carried out through the oxide layer and/or a coverage in some regions in the recesses through the masking layer.

It also lies in the scope of the invention to form the method according to the invention for producing so-called emitter wrap through (EWT solar cells). The result of the processing steps corresponds essentially to the sequence for producing a MWT solar cell. However, in the case of EWT solar cells, there is no metallization or not sufficient metallization with respect to the electrical conductivity from the front side to back side in the recesses. Instead, on the walls of the recesses, emitters are guided from the front side to back side of the silicon substrate, so that, in this way, the emitter can be contacted on the back side and is connected in an electrically conductive way to the emitter on the front side by means of the emitter formation on the hole walls. Accordingly, in this advantageous embodiment, in processing step F, no metallization is deposited on the front side, but instead both the metallization structures for contacting the emitter and also the metallization structures for contacting the base are deposited on the back side.

In the method according to the invention, advantageously the masking step in step D is deposited as an anti-reflection layer on the front side of the silicon substrate and accordingly the oxide layer is deposited in processing step E2 by means of thermal oxidation on the back side of the silicon substrate. In particular, it is advantageous to form the emitter region in step E on the front side of the silicon substrate.

In this advantageous embodiment of the method according to the invention, it is further advantageous when the metallization structure is deposited by means of a screen-printing method on the front side in processing step F. Because the formation of the masking layer as an anti-reflection layer, in particular, the formation as a silicon nitride layer has the advantage that the masking layer represents protection against all essential processing steps for the surface of the silicon substrate lying underneath, while a metal-containing screen-printing paste deposited on the masking layer penetrates the masking layer, in particular, the silicon nitride layer for application of the typical processing steps and thus there is an electrical connection between the metallization structure and the emitter lying under the masking layer. This is based on the fact that anti-reflection layers, in particular, a silicon nitride layer, are penetrated by the typically used screen-printing pastes that contain frit in the typically applied temperature steps. The property that the masking layer can be penetrated during a firing process is maintained despite the thermal oxidation (step E2).

Advantageously, in processing step F, initially a printing of a metallization paste is therefore carried out by means of screen printing on the front side, i.e., on the masking layer and then a printing of the back side with a metal-containing layer, advantageously with a silver-containing paste on the front side and an aluminum-containing paste on the back side. It also lies in the scope of the invention to apply other printing methods instead of screen printing, for example, aerosol printing, pad printing, stencil printing of the dispensers, or printing by means of inkjet methods. It also lies in the scope of the invention to change the sequences of the metallization steps and also the firing process. In addition to the mentioned printing methods, other methods, for example, galvanic deposition of nickel or silver or other metals, or deposition by means of PVD processes, such as vapor deposition or sputtering of metals, such as, for example, titanium, nickel, tungsten, or silver, could also be used in the scope of the invention for the metallization of the solar cell. Metal layer systems made from various metals could also be used.

Then a temperature step for producing the contacts of the front side is carried out, wherein the back side could also be already contacted when, for example, openings are formed in the back-side coating or the LFC process described below is carried out before the temperature step for producing the contacts of the front side.

For producing the back-side contacts, it is especially advantageous that known methods of LFC contacting (laser fired contacts) are to be used in which, by means of a laser, a melting of the deposited aluminum layer is carried out point-by-point on the back side and the underlying layers including a thin region of the silicon substrate, so that, after re-solidification of the molten region, an electrical contacting exists between the aluminum layer and the silicon substrate.

In addition, in the scope of the invention, after the contact formation, a reinforcement of the metallization can also be achieved through galvanic processes. It is especially advantageous here that, through the process of thermal oxidation, possible defects are covered in the masking layer deposited in step D by thermal oxide and thus a parasitic deposition of metals in the galvanic process can be stopped.

Advantageously, in the method according to the invention, a tempering process is finally carried out in which the quality of the passivation layers and/or the contact can be improved. Such a process could be carried out under various atmospheres. For example, mixtures of hydrogen and nitrogen, or hydrogen and argon are possible. Purified compressed air or only nitrogen could also be used. As the processing apparatus, a tubular furnace or also a tunnel machine could be used.

Additional features and advantageous embodiments of the method according to the invention result from the embodiments and figure descriptions described below. Shown herein are:

### BRIEF DESCRIPTION OF THE DRAWINGS

FIGS. 1 and 1a: a schematic diagram of an embodiment of the method according to the invention for producing a solar cell with front-side and back-side contacts,

FIGS. 2, 2a, and 2b: a schematic diagram of an embodiment of the method according to the invention for producing an MWT solar cell,

FIGS. 3 and 3a: a schematic diagram of another embodiment of the method according to the invention for producing an MWT solar cell,

FIG. 4: the front side of the solar cell produced by the method shown in FIGS. 1, 1a,

FIG. 5: the front side of a solar cell produced by the method shown in FIGS. 2, 2a, 2b or FIGS. 3, 3a, and

FIG. 6: the back side of a solar cell produced by the method shown in FIGS. 2, 2a, 2b or FIGS. 3, 3a.

### DETAILED DESCRIPTION OF THE PREFERRED EMBODIMENTS

In the three embodiments described below, the silicon substrate 1 is formed in each case as a monocrystalline silicon wafer with an approximately square surface area with an edge length of approximately 12.5 cm. The thickness of the wafer equals approximately 250 μm. The wafer is homogeneously p-doped.

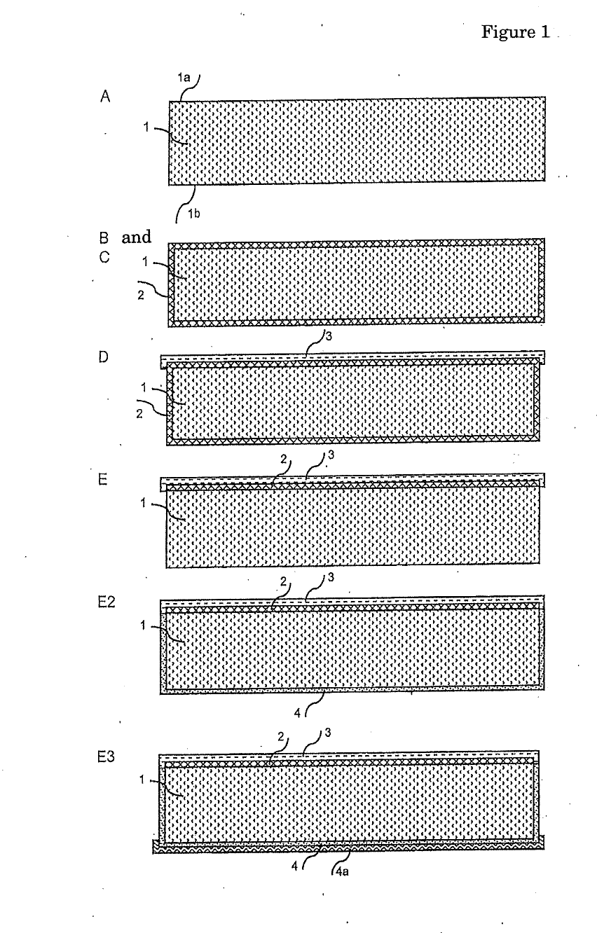

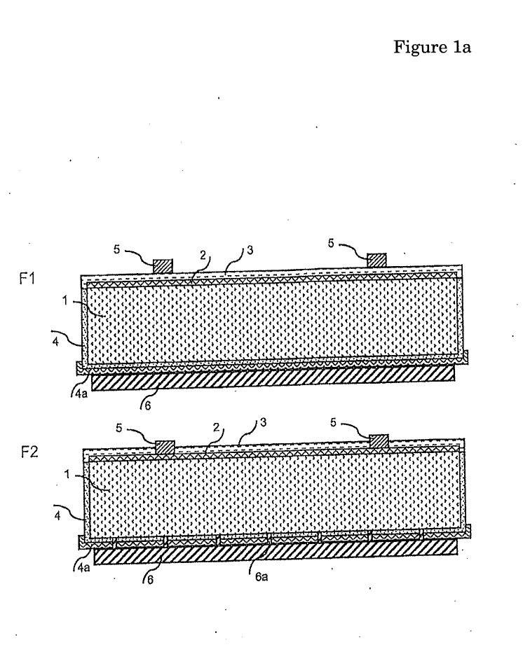

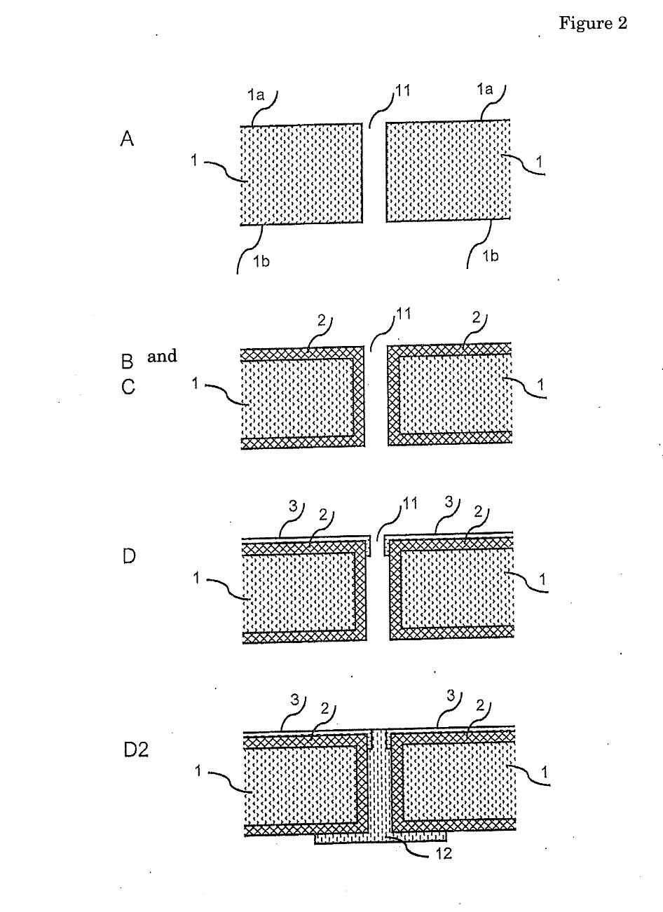

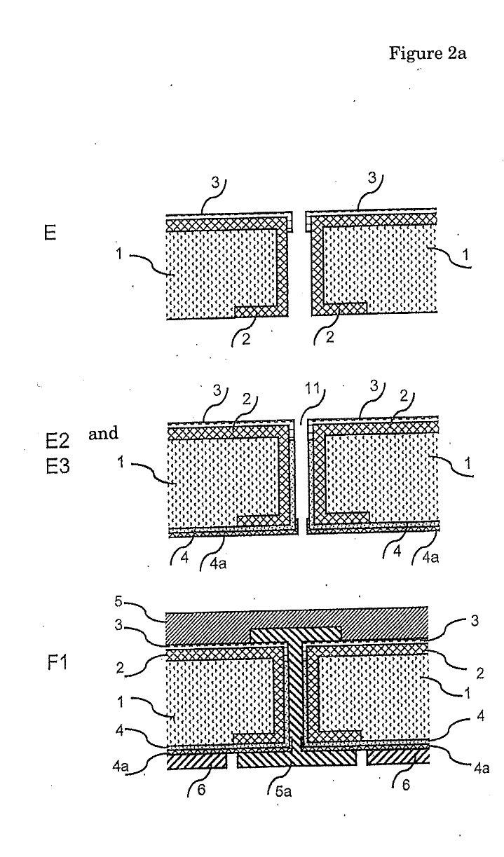

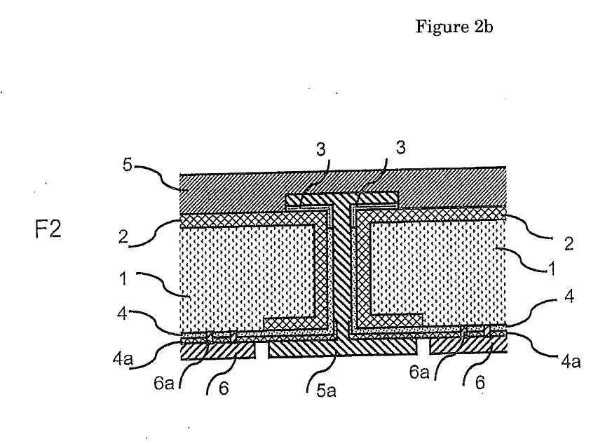

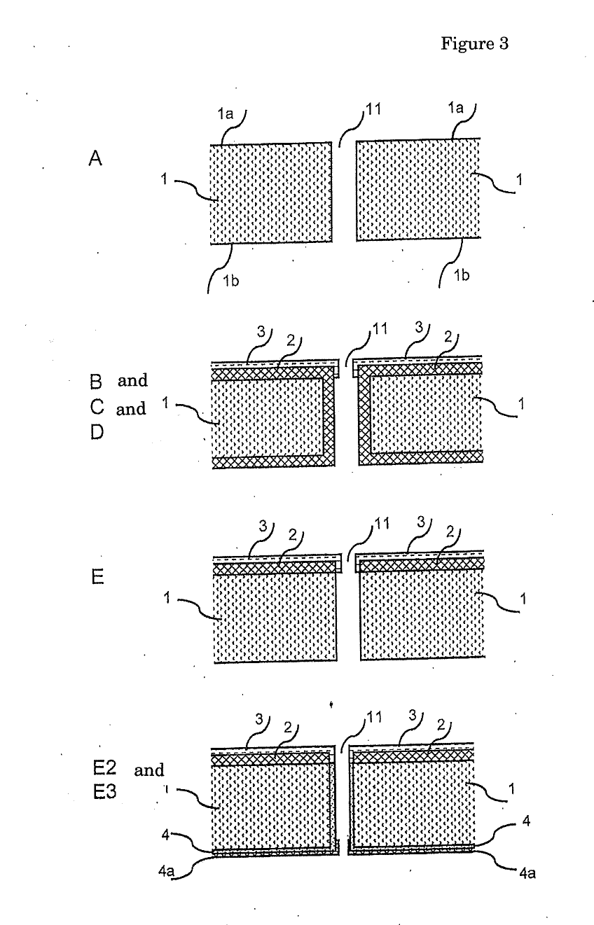

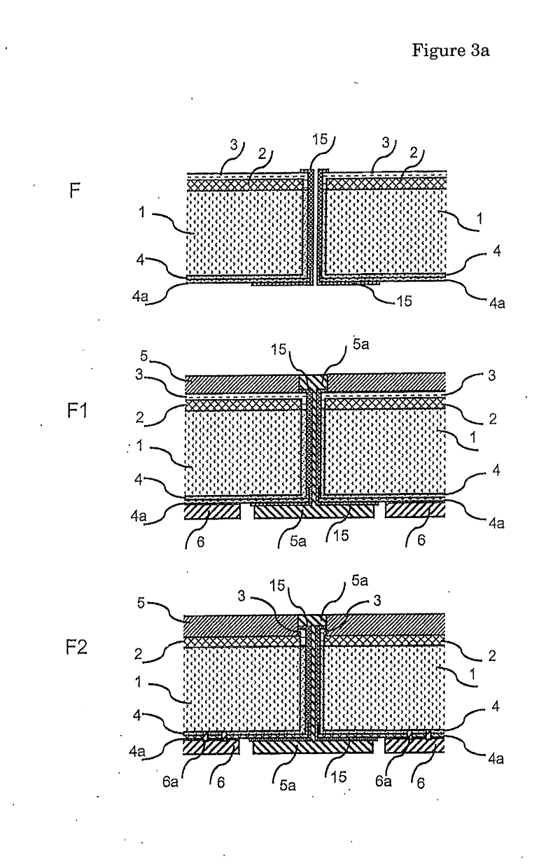

FIGS. 1 to 3 each show a schematic cross section not drawn to scale through the silicon substrate 1, wherein the front side 1a is shown at the top and the back side 1b is shown at the bottom. The cross section here shows, in the case of FIGS. 2 to 3, not the entire width of the silicon substrate, but instead merely a section from this width. For better presentability, the number of identical elements is reduced, for example, the number of contacts 6a.

In the embodiment shown in FIGS. 1 and 1a, in a processing step A, a texture is generated on the front side 1a in an alkali solution containing KOH. Here, the wafer is dipped into a caustic potash solution. The solution could also contain, in addition to the caustic potash, organic additives, such as isopropanol. The temperature of the solution lies in the range of ca. 80° C. The concentration of the caustic potash and that of the isopropanol equal approximately 1-7%. Then the wafer is still cleaned in HCl (hydrochloric acid) (10%, 1 min., ambient temperature) and a final HF (hydrofluoric acid) etching process (1%, 1 min., ambient temperature).

Here, possible cutting damage resulting from the sawing of the silicon substrate 1 is likewise removed from a silicon block from the front side and the back side.

Then, in a step B, an emitter 2 is generated on all of the surfaces of the silicon substrate 1 by means of phosphorus diffusion from the gas phase. This is carried out by deposition of a dopant source and at an elevated temperature. As the dopant source, for example, phosphorus oxichloride POCl3 could be used. In a tubular furnace system, the POCl3 is deposited on the wafer and the diffusion is carried out at temperatures of ca. 850° C. for ca. 50 minutes. Diffusion processes could also be carried out in which only sub-regions of the wafer are provided with diffusion, so that an emitter is formed only at sub-regions of the surface of the silicon substrate.

Then, in a step C, the phosphorus silicate glass forming during the diffusion of the emitter is removed from the surfaces of the silicon substrate. For removal of the phosphorus silicate glass or other residual dopant sources, the wafer is dipped, for example, for 2 minutes in hydrofluoric acid (ca. ambient temperature and ca. 5% HF in water).

In a step D, a masking layer 3 that has an index of refraction of ca. 2.1 and is formed as a silicon nitride layer (SiNx) is then deposited essentially on the front side 1a of the silicon substrate 1. The layer 3 is generated with a thickness of ca. 80 nm, wherein the layer thickness could be adapted in the original thickness as a function of the subsequent processing steps, in order to have an optimal thickness after completion of the process. The coating is carried out on the side of the wafer facing the light.

For this purpose, a PECVD (plasma-enhanced chemical vapor deposition) method or a sputtering method is used.

In a step E, a removal of material of the silicon substrate 1 is carried out, wherein the masking layer 3 prevents removal as long as the removal is not otherwise carried out by a method that is active on one side and in which substances can also be used that could attack layer 3, so that, after completion of the processing step E, the emitter diffused in processing step B was removed, with the exception of the front-side region of the silicon substrate 1 covered by the masking layer 3. The wafer is here coated on one side on the back side with a liquid HNO3:HF mixture. This removes possible excess residues of SiN on the back side (HNO3: nitric acid).

Then the wafer is dipped in a caustic potash (10% KOH, 5 min., 80° C.), in order to smooth the wafer surface and to remove possibly still present emitter at all points that are not covered with SiN.

Then a conditioning of the surface is carried out in several steps, advantageously with the specified processing parameters:
1. NH4OH:H2O2 (ammonium hydroxide:hydrogen peroxide in water; (NH4OH 7.1 Wt. %, H2O2 1 Wt. %, 10 Min, 65° C.)
2. Rinsing in DI water
3. HF dip (hydrofluoric acid in water 1 wt. %, 1 min. at ambient temperature)
4. Rinsing in DI water
5. HCl:H2O2 (hydrochloric acid:hydrogen peroxide in water; HCl 8.5 wt. %, H2O2 1 wt. %, 10 min., 65° C.)
6. Rinsing in DI water
7. HF dip (see above)
8. Rinsing in DI water

In a processing step E2, by means of the thermal oxidation, an oxide layer 4 is deposited. Here, the masking layer 3 formed as a silicon nitride layer has an inhibiting effect relative to the configuration of an oxide layer, so that the oxide layer 4 forms essentially only on the surfaces of the silicon substrate 1 that are not covered by the masking layer 3. The thermal oxidation is carried out in a water-vapor-containing atmosphere (ca. 800° C., 20 min.). An oxide layer with a thickness of ca. 15 nm is produced. Other processing temperatures (for example, in the range of (550° C.-1050° C.)) and times (for example, in the range (10 sec.-300 min.) could also be selected for the oxidation, in order to bring about suitable layers.

For shortening the oxidation times, in particular, oxidation temperatures of 700° C.-1050° C. with an oxidation time in the range 2 min-180 min and especially advantageous oxidation temperatures of 750° C.-1000° C. with an oxidation time in the range 3 min-80 min could also be selected.

For better passivation of the back side of the silicon substrate 1, in a processing step E3 on the oxide layer 4, a second layer 4a is deposited that is formed as a multi-layer structure with a layer sequence of silicon oxynitride and silicon nitride.

In a processing step F1, by means of screen printing, a comb-like metallization structure 5 is deposited on the front side of the silicon substrate 1, i.e., on the masking layer 3, wherein for creating the front-side metallization, a silver-containing screen-printing paste is used. Alternatively, other metal pastes could also be used that create a contact to the silicon.

In processing step F1, the back side is also provided by means of screen printing over the entire surface area with a back-side metallization 6 (thickness ca. 30 μm) that is built accordingly on the layer system consisting of the oxide layer 4 and second layer 4a. In a step F2, finally a so-called “through firing” of the front-side contacts 5 is carried out, i.e., a temperature step is carried out (at ca. 850° C.) that leads to a penetration of the front-side contacts 5 through the masking layer 3, so that an electrical contact is produced between the front-side contacts 5 and emitter region.

Alternatively, the metallization of the back side is realized by means of the deposition of a thin aluminum layer (ca. 2 μm) by means of PVD, advantageously after carrying out the through-firing step.

On the back side, individual local regions are temporarily melted by a laser, so that also after solidification of the molten mixture, a penetration of the back-side layer system through the back-side metallization 6 is carried out and thus there is an electrically conductive connection between the back-side metallization 6 and the p-doped region of the silicon substrate 1. The generation of such laser-fired contacts is described, for example, in WO0225742.

Finally, the solar cell is subjected to a low-temperature process (ca. 350° C., 5 min) in a forming-gas atmosphere (N2/H2 mixture 95%/5%).

The processing parameters of the individual processing steps could also be equipped, for example, like in the publication mentioned above, Industrial Type Cz Silicon Solar Cells With Screen-Printed Fine Line Front Contacts And Passivated Rear Contacted By Laser Firing. Marc Hofmann et al., 23rd European Photovoltaic Solar Energy Conference and Exhibition, Sep. 1-5, 2008, Valencia, Spain. One essential difference, however, is that, in the mentioned publication, no thermal oxide is deposited on the back side of the silicon substrate, but instead a layer system is generated by means of PECVD.

In FIGS. 2, 2a, and 2b, an embodiment of the method according to the invention is shown for production of an MWT solar cell.

Identical reference symbols here designate identical elements like also for the production method described for FIGS. 1 and 1a. Processing steps with identical designations also advantageously have essentially identical constructions.

The method for producing an MWT solar cell according to FIGS. 2, 2a, and 2b, however, includes a preceding, not-shown processing step A0 in which, in the silicon substrate 1, several recesses that are advantageously represented by cylindrical holes are formed in the silicon substrate 1. With a laser, the recesses are generated in the silicon wafer. These holes have a diameter of ca. 60 μm. Other hole geometries are also possible.

In FIGS. 2, 2a, and 2b, in each case, one of these recesses is shown in the schematic section drawing in the center, wherein the cylinder axis of the cylindrical recess is perpendicular in FIGS. 2, 2a, and 2b, i.e., perpendicular to the front side 1a of the silicon substrate 1.

Accordingly, in processing step B, the emitter also forms on the walls of the recesses 11.

Therefore, in an additional processing step D2, after deposition of the masking layer 3, a protective hole filling 12 is formed in the recesses. The protective hole filling 12 is here constructed such that it covers, on the back side of the silicon substrate 1, a region of the back side around the recesses in addition to the walls of the recess. Pastes or coatings that are built, for example, on organic substances and feature corresponding resistances could be the protective hole filling. Inorganic connections could also be suitable here.

Alternatively, the protective hole filling could also be formed after processing step B or C.

This has the result that, in processing step E, the emitter remains not only on the front side and the hole walls of the recess 11, but also on a sub-region of the back side of the silicon substrate 1. In processing step E, the state is already shown after the protective hole filling was removed.

The insertion and removal of the protective hole fillings is here carried out, for example, through local printing (the arrangement of the substance is also possible through other technologies, e.g.: dispensers, inkjets) of a substance on the back side of the wafer and in the holes (wherein at least the hole walls must be covered), which substance protects these parts in the subsequent processing steps in which the silicon is attacked on the uncoated regions. On the back side and in the holes, regions of (4) remain that were not removed. Before the oxidation, the substance is removed.

Then, in processing step 2 and E3, as already explained for FIG. 1, 1a, a layer system with an oxide layer 4 and a second layer 4a constructed as a multi-layer system is formed on the back side of the silicon substrate. This layer system consequently also extends partially onto the walls of the recesses 11.

In a step F, the metallization is finally carried out, wherein the front-side contacts 5 are constructed in this embodiment as through contacts that penetrate the recesses and thus represent an electrical contact from the front side to the back side, allowing a contacting of the emitter from the back side of the solar cell.

The front-side contacts 5 are here constructed such that they penetrate, for one, the recesses, but, on the other hand, cover, in all cases, on the back side of the silicon substrate, a region that is smaller than the region covered by the emitter on the back side. In this way, short circuits are avoided that would then occur if the front-side contact 5 would form an electrical contact to the p-doped region of the silicon substrate. The through contacting could also be carried out by the use of different pastes, wherein the front-side contacts 5 are initially not guided into the recesses and on the back side. The feed through is generated by the use of another via paste 5a that produces an electrical contact to the front-side contacts 5.

The remaining regions of the back side are covered over a surface area with a metallization as also already described for FIGS. 1, 1a that form contacts that are electrically conductive by means of local melting by a laser to the p-doped region of the silicon substrate.

For avoiding short circuits, a specified region is cut out on the back side of the silicon substrate between the front-side contacts 5 and the back-side metallization 6.

The generation of the front-side contacts 5 and back-side metallization 6 comprises the following processing steps:
1. Printing of back-side contacts 6 (advantageously containing aluminum)
2. Printing of a via paste 5a (advantageously containing silver) that generates, on the back side of the solar cell, a metallization that has an electrical contact with the metallization of the front side through the holes
3. Printing of front-side contacts (advantageously containing silver)
4. Firing of the contacts (at ca. 850° C.)
5. Local contact formation between aluminum layer and silicon by means of a laser that drives the aluminum point-by-point through the intermediate layer and thus generates a contact 6a according to the method of the laser-fired contacts (as described, for example, in WO0225742).

Alternatively, the deposition (for example, by printing) of the via paste is carried out in Step No. 2 after Step No. 4 or after Step No. 5 or also after the low-temperature process named below. To this end, the via paste could also be formed, for example, merely as a conductive adhesive or solder paste and must have only metallic components, in order to produce a contact to the front-side contact 5 and to guarantee a contact feedthrough.

Finally, the solar cell is subjected to a low-temperature process (ca. 350° C., 5 min.) in a forming gas atmosphere (N2/H2 mixture 95%/5%).

The embodiment shown in FIGS. 2, 2a, and 2b of the method according to the invention represents a preferred method for producing MWT solar cells in which an especially high safety is produced by the protective hole fillings in step D2 and the corresponding emitter 2 remaining partially on the back side, such that no short circuits occur between n-doped regions and p-doped regions of the solar cell or between front-side contacts and back-side metallization and therefore a negative effect on the efficiency of the solar cell by short circuits is avoided.

For simplifying the method and, in particular, for more economical constructions of the method, a second embodiment of the method according to the invention is shown in FIGS. 3 and 3a for producing an MWT solar cell.

In this method, no protective hole filling is constructed between the processing steps D and E. The processing steps A, B, C, D, E, E2, and E3, as well as F correspond to the processing steps described for FIGS. 2, 2a, and 2b.

However, due to the non-present protective hole filling, the emitter remains only on the front side 1a of the silicon substrate and not on the hole walls of the recesses 11 (to a large extent not covered by layer 3) and also not on sub-regions of the back side of the silicon substrate 1.

Accordingly, after feed through by the recesses 11, the front-side metallization lies on the back side on the layer system. Because the layer system is not electrically conductive, there is no short circuiting to the p-doped region of the silicon substrate. However, relative to the method described for FIGS. 2, 2a, and 2b, there is a greater risk that either on the back side or on the hole walls of the recesses 11, there is a short circuit between the front-side contacts 5 and the p-doped region of the silicon substrate. In contrast, the production method described for FIGS. 3 and 3a can be realized significantly more easily and economically.

The metallization in step F comprises, in the embodiment shown in FIGS. 3 and 3a, the following processing steps:
1. Printing of front-side contacts 5 (advantageously containing silver)
2. Printing of back-side contacts 6 (advantageously containing aluminum)
3. Firing of the contacts (at ca. 850° C.)
4. Local contact formation between aluminum layer and silicon by means of a laser that drives the aluminum point-by-point through the intermediate layer and thus generates a contact 6a according to the method of laser-fired contacts (as described, for example, in WO0225742).

Finally, the solar cell is subjected to a low-temperature process (ca. 350° C., 5 min.) in a forming-gas atmosphere (N2/H2 mixture 95%/5%).

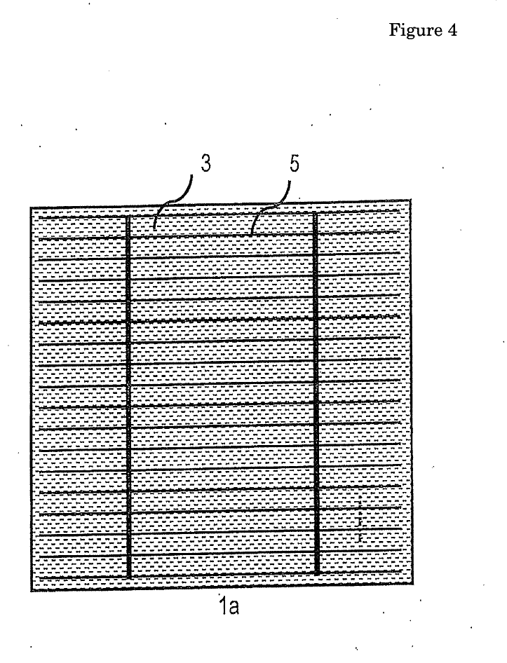

FIG. 4 shows, in a schematic diagram, the front side 1a of the solar cell produced by the method shown in FIGS. 1, 1a in top view. On the masking layer 3 formed as an anti-reflection layer, a comb-like metallization structure is constructed that forms the front-side contacts 5.

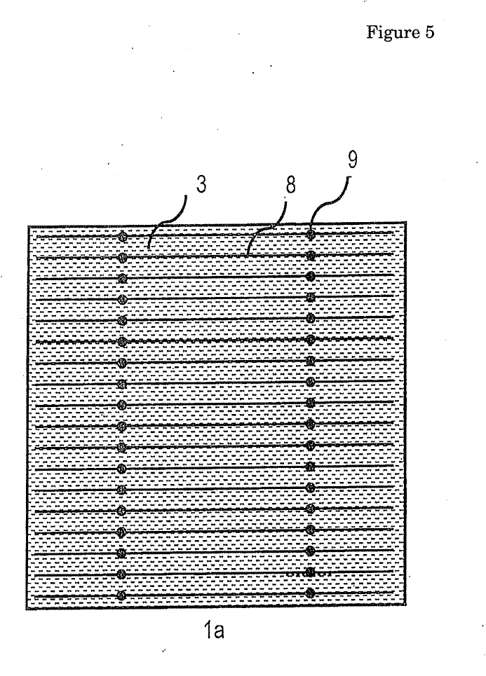

In FIG. 5, the front side of a solar cell produced by the method shown in FIGS. 2, 2a, and 2b or FIGS. 3 and 3a is shown schematically in top view. Here, for increasing the light coupling on the front side of the solar cell, no comb-like metallization structure is constructed. Instead, several parallel metallization lines 8 that each run over the recesses in the silicon substrate are constructed on the masking layer 3, wherein, in each case, through metallization structures that extend from the front side to the back side of the solar cell are constructed in the recesses. The position of the through metallization structures is marked by circles and, as an example, with the reference symbol 9.

The metallization lines 8 are thus part of the front-side contacts that are designated in the section images of FIGS. 2, 2a, and 2b or FIGS. 3 and 3a with the reference symbol 5.

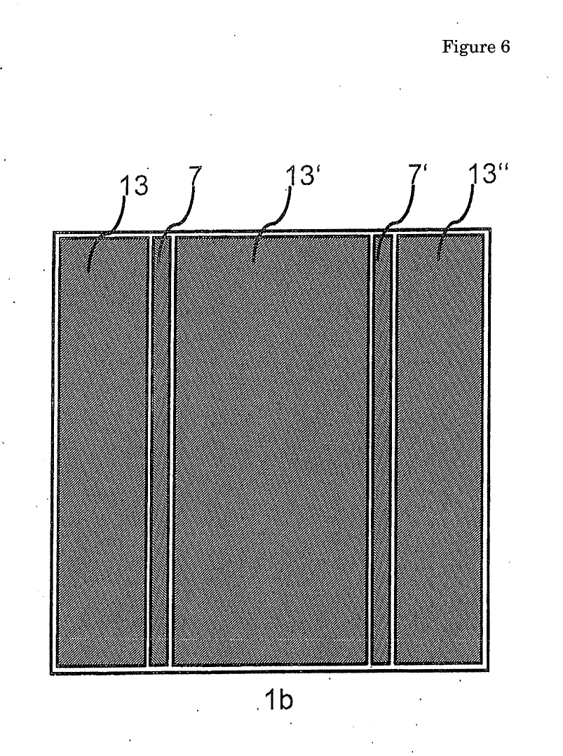

In FIG. 6, the back side of a solar cell produced by the method shown in FIGS. 2, 2a, and 2b or FIGS. 3 and 3a is shown in top view.

The back side has three large surface area back-side metallization regions 13, 13′, and 13″. Between the regions, linear metallization regions 7 and 7′ are constructed, wherein there is an intermediate space between the metallization regions, so that the individual metallization regions are isolated electrically from each other.

The back-side metallization regions 13, 13′, and 13″ thus correspond to the back-side metallization structures 6 shown in FIGS. 2, 2a, and 2b or FIGS. 3 and 3a. These back-side metallization regions are connected to each other in an electrically conductive way by means of the base.

The metallization regions 7 and 7′ run along the recesses in the silicon substrate and perpendicular to the metallization lines 8 on the front side of the solar cell. These metallization regions are connected to each other in an electrically conductive way by means of the emitter.

The metallization regions 7 and 7′ thus correspond to the front-side contacts 5a shown in FIGS. 2, 2a, and 2b or FIGS. 3 and 3a.

The metallization lines 7 are thus connected in an electrically conductive way to all of the metallization lines 8. In this way, the base of the solar cell can be contacted by means of the metallization structures 13, 13′, and 13″ and the emitter of the solar cell can be contacted by means of the metallization structures 7 and 7′.

The terms “after” and “then” refer, in all of the preceding uses with respect to processing steps, merely to processing steps carried out one after the other in the processing sequence and comprise processing steps carried out both directly and also indirectly one after the other.

1. Method for producing a solar cell with a front side and a back side from a silicon substrate (1), comprising the following processing steps:
A) generating a texture on at least one side of the silicon substrate (1) for at least one of improving absorption when electromagnetic radiation is incident on the solar cell or for removal of cutting damage on at least one side of the silicon substrate (1),
B) generating at least one emitter region (2) at least on sub-regions of at least one side of the silicon substrate (1) through diffusion of at least one dopant for forming at least one pn junction,
C) removing a glass layer on at least one side of the silicon substrate (1), wherein the glass layer contains the dopant,
D) depositing a masking layer (3) at least on one sub-region of at least one side of the silicon substrate (1), wherein the masking layer (3) is a dielectric layer,
E) removing at least one part of the material of the silicon substrate (1) on at least one side of the silicon substrate (1) and/or conditioning at least one side of the silicon substrate (1),
F) depositing metallization structures (5, 6) on at least one of the front side (1a) or back side (1b) of the silicon substrate (1) for electrical contacting of the solar cell, and
between the processing steps E and F, in a processing step E2, carrying out a thermal oxidation for the formation of an oxide layer (4) at least in one sub-region of at least one of the front side or back side of the silicon substrate (1), wherein the sub-region is not covered by the masking layer (3) deposited in step D, and
the masking layer (3) and the oxide layer (4) essentially remain on the silicon substrate (1) in subsequent processing steps.

2. Method according to claim 1, wherein the masking layer (3) is selected such that it inhibits formation of an oxide layer generated by thermal oxidation on and/or below the masking layer.

3. Method according to claim 1, wherein in processing step D, the masking layer (3) is deposited essentially only on one masking layer side that is the front side or the back side of the silicon substrate (1), and in processing step E, on the side of the silicon substrate opposite the masking layer side, a one-side material removal is carried out for removing any sub-pieces of a masking layer (3) undesirably deposited on the side opposite the masking layer side.

4. Method according to claim 3, wherein in processing step E, initially the one-side material removal is carried out that removes at least undesired sub-regions of the masking layer (3) and then another material removal is carried out that removes the masking layer (3) not at all or only insignificantly.

5. Method according to claim 1, wherein the masking layer (3) has a density between 2.3 g/cm³ to 3.6 g/cm³.

6. Method according to claim 1, wherein in processing step E2, the oxide layer (4) is deposited with a thickness in a range between 4 nm and 250 nm.

7. Method according to claim 1, wherein between the processing steps E2 and F, in a processing step E3, at least one additional layer is deposited on the oxide layer (4).

8. Method according to claim 1, wherein the masking layer (3) is an anti-reflection layer for improving a coupling of electromagnetic radiation into the solar cell.

9. Method according to claim 1, wherein in step F, a metallization structure (5) is deposited on the masking layer (3) and a penetration of the metallization structure at least in some regions is carried out through the masking layer, such that the metallization structure is connected in an electrically conductive way to the silicon substrate lying under the masking layer.

10. Method according to claim 1, wherein before processing step A, in a processing step A0, several recesses (11) are formed in the silicon substrate (1), wherein the recesses penetrate the silicon substrate essentially perpendicular to the front side (1a).

11. Method according to claim 10, wherein after processing step B, a layer is deposited in the recesses (11) and on adjacent surface regions, so that, in the processing step E, no removal of the emitter is carried out under the layer.

12. Method according to claim 10, wherein the recesses (11) have an average diameter of 20 μm to 3 mm.

13. Method according to claim 10, wherein in processing step F, both on the front side and also on the back side of the silicon substrate (1), metallization structures (5, 6) are deposited and a feed through of the front-side metallization structure is carried out by metallization structures in the recesses on the back side of the silicon substrate (1).

14. Method according to claim 13, wherein between the processing steps E2 and F, an electrically insulating layer (4) is deposited in the recesses (11).

15. Method according to claim 1, wherein after processing step E2, recesses are generated in the oxide layer (4) and optionally in the layer or layers generated in a processing step E3 for contacting the silicon substrate (1).

16. Method according to claim 1, wherein in processing step F or in a subsequent processing step, the metallization structure is increased in conductivity by a galvanic process.

17. Solar cell produced according to a method according to claim 1.
